(19) United States
(12) Patent Application Publication
(10) Pub. No.: US 2013/0110434 A1
(43) Pub. Date: May 2, 2013

(54) METHOD AND ARRANGEMENT FOR DETECTING FREQUENCY AND FUNDAMENTAL WAVE COMPONENT OF THREE-PHASE SIGNAL

(71) Applicant: ABB Research Ltd, Zurich (CH)

(72) Inventors: Ngai-Man HO, Zurich (CH); Gerardo ESCOBAR, Merida (MX); Sami PETTERSSON, Zurich (CH)

(73) Assignee: ABB Research Ltd, Zurich (CH)

(21) Appl. No.: 13/666,649

(22) Filed: Nov. 1, 2012

(30) Foreign Application Priority Data
Nov. 1, 2011 (EP) 11187366.7

(51) Int. Cl. G06F 19/00; G01R 19/00

(52) U.S. Cl. 702/64

(57) ABSTRACT

A method and arrangement for detecting a frequency of a measured three-phase voltage. The method includes measuring a three-phase voltage, forming a discrete model for a periodic signal, the discrete model including the three-phase voltage and a difference between positive and negative voltage components of the three-phase voltage, forming a discrete detector based on the discrete model, detecting a fundamental wave component of the voltage and the difference between the positive and negative voltage components of the three-phase voltage from an error between the measured voltage and detected fundamental wave component of the voltage by using the discrete detector and a sampling time together with a detected frequency of the measured voltage. The detected frequency is detected from a detected difference between positive and negative voltage components of the measured voltage and from an error between the measured voltage and the detected fundamental wave component of the voltage.

### RELATED APPLICATIONS

This application claims priority under 35 U.S.C. §119 to European Patent Application No. 11187366.7 filed in Europe on Nov. 1, 2011, the entire content of which is hereby incorporated by reference in its entirety.

### FIELD

The present disclosure relates to phase-locked loops. More particularly, the present disclosure relates to discrete phase-locked loops used for detection of angular frequency and a fundamental wave component of a reference signal.

### BACKGROUND INFORMATION

Many applications involve the detection of fundamental angular frequency and extraction of a clean balanced three-phase sinusoidal signal, for example, the positive sequence of a fundamental wave component. The latter can be synchronized with a three-phase reference signal, despite the presence of severe unbalance and high harmonic distortion. In particular, detection of the fundamental angular frequency is used for the synchronization of three-phase grid connected systems such as power conditioning equipment, flexible ac transmission systems (FACTS), power line conditioners, regenerative drives, uninterruptible power supplies (UPS), grid connected inverters for alternative energy sources, and other distributed generation and storage systems.

A known three-phase phase-locked loop (PLL) based on a synchronous reference frame (SRF-PLL) is perhaps the most extended technique used for frequency-insensitive positive-sequence detection. Different schemes have been proposed based on this known scheme, and most of them relay in a linearization assumption. Thus, the results can be guaranteed locally only. These schemes have an acceptable performance under ideal utility conditions, that is, without harmonic distortion or unbalance. However, under more severe disturbances, the bandwidth of the SRF-PLL feedback loop must be reduced to reject and cancel out the effect of harmonics and unbalance on the output. However, the PLL bandwidth reduction is not an acceptable solution as its speed of response is considerably reduced as well.

Few digital PLL schemes have appeared in the literature so far. Most of them have been referred to as DPLL. In M. A. Perez, J. R. Espinoza, L. A. Moran, M. A. Torres, and E. A. Araya, “A robust phase-locked loop algorithm to synchronize static power converters with polluted AC systems,” IEEE Trans. on Industrial Electronics, Vol. 55(5), pp. 2185-2192, May 2008, a discrete PLL is disclosed for a single-phase synchronization application. It is a zero crossing detection method, which uses a structure similar to that of the known PLL, except that discrete filters are used, with additional advantages. One of the main characteristics is the possibility to adjust a sampling period according to a fundamental frequency, to allow integer multiple of sampling periods per fundamental period. It is, however, very sensitive to severe voltage disturbances.

In B. Y. Ren; Y. R. Zhong, X. D. Sun; X. Q. Tong, “A digital PLL con-trol method based on the FIR filter for a grid-connected single-phase power conversion system,” in Proc. IEEE International Conference on Industrial Technology ICIT08, 2008, pp. 1-6., a discrete PLL method is disclosed for the single phase synchronization problem. However, the authors use the approach of extending single phase signals to virtual three-phase signals represented in synchronous frame coordinates. The discrete part comes out of the application of two FIR filters, one to produce the x-coordinate and the other to produce the y-coordinate, i.e. its orthogonal signal. Then the rest of the scheme is very similar to the known SRF-PLL used for three-phase systems.

PLL based controllers are usually implemented digitally. Consequently, the PLL scheme has to be discretized by using approximate discretization rules in most cases. This approach may work properly for a high sampling frequency; however, it may lead to inaccuracies in cases of a relatively low sampling frequency.

### SUMMARY

An exemplary embodiment of the present disclosure provides a method of detecting a frequency of a measured three-phase voltage. The exemplary method includes measuring the three-phase voltage (ν_{αβ}), and forming a discrete model for a periodic signal, the discrete model including the three-phase voltage (ν_{αβ}) and a difference (φ_{αβ,k}) between a positive voltage component and a negative voltage component of the three-phase voltage as model variables. The exemplary method also includes forming a discrete detector based on the formed discrete model, and detecting a fundamental wave component of the voltage (\hat{ν}_{αβ,1}) and the difference (\hat{φ}_{αβ,1}) between the positive voltage component and the negative voltage component of the three-phase voltage from an error (\tilde{ν}_{αβ}) between the measured voltage (ν_{αβ}) and the detected fundamental wave component of the voltage (\hat{ν}_{αβ,1}) by using the discrete detector and a sampling time (Tₛ) together with a detected frequency (\hat{ω}₀) of the measured voltage. The detected frequency (\hat{ω}₀) of the measured voltage is detected from a detected difference (\hat{φ}_{αβ,k}) between positive and negative voltage components of the measured voltage and from the error (\tilde{ν}_{αβ}) between the measured voltage (ν_{αβ}) and the detected fundamental wave component of the voltage (\hat{ν}_{αβ,1}) in an adaptation mechanism.

An exemplary embodiment of the present disclosure provides an arrangement for detecting the frequency of a measured three-phase voltage. The exemplary arrangement includes means for measuring the three-phase voltage (ν_{αβ}), and a discrete model for a periodic signal, the discrete model including the three-phase voltage (ν_{αβ}) and a difference (φ_{αβ,k}) between a positive voltage component and a negative voltage component of the three- phase voltage as model variables. The exemplary arrangement also includes a discrete detector based on the formed discrete model, and means for detecting a fundamental wave component of the voltage (\hat{ν}_{αβ,1}) and the difference (\hat{φ}_{αβ,1}) between the positive voltage component and the negative voltage component of the three-phase voltage from an error (\tilde{ν}_{αβ}) between the measured voltage (ν_{αβ}) and the detected fundamental wave component of the voltage (\hat{ν}_{αβ,1}) by using the discrete detector and a sampling time (Tₛ) together with a detected frequency (\hat{ω}₀) of the measured voltage. The detected frequency (\hat{ω}₀) of the measured voltage is detected from a detected difference (\hat{φ}_{αβ,k}) between positive and negative voltage components of the measured voltage and from the error (\tilde{ν}_{αβ}) between the measured voltage (ν_{αβ}) and the detected fundamental wave component of the voltage (\hat{ν}_{αβ,1}) in an adaptation mechanism.

### BRIEF DESCRIPTION OF THE DRAWINGS

Additional refinements, advantages and features of the present disclosure are described in more detail below with reference to exemplary embodiments illustrated in the drawings, in which:

FIG. 1 shows a block diagram of a dPLL-UH method including a discrete harmonic compensation mechanism dCM-UH for an unbalanced and distorted reference signal;

FIG. 2 shows a block diagram of a discrete unbalanced harmonic compensation mechanism dCM-UH including unbalanced harmonic oscillators tuned at 3rd, 5th, and k-th harmonic;

FIG. 3 shows comparisons between transient responses during start- up of a detected fundamental frequency (rad/s);

FIG. 4 shows transient responses, changing from balanced to unbalanced operation, of the detected fundamental frequency;

FIG. 5 shows transient responses, changing from balanced to unbalanced operation, of the detected fundamental frequency;

FIG. 6 shows a transient response of the proposed dPLL-UH when a reference signal changes from a balanced to an unbalanced condition;

FIG. 7 shows a transient response of the proposed dPLL-UH when harmonic distortion is added to the already unbalanced reference signal;

FIG. 8 shows a transient response of the detected fundamental frequency (rad/s) when harmonic distortion is added to the reference signal;

FIG. 9 shows a transient response of the proposed dPLL-UH to a distorted unbalanced reference signal when a utility frequency changes from 50 Hz to 35 Hz; and

FIG. 10 shows a steady state response of a detected positive-sequence of a fundamental wave component.

### DETAILED DESCRIPTION

Exemplary embodiments of the present disclosure provide a method and an arrangement for implementing the method so as to solve the above-described problem. Exemplary features of the method and arrangement are described in more detail below.

The present disclosure is of special relevance in cases where digital implementation of an overall synchronization method uses a low sampling frequency. In such a case, the method of the present disclosure provides a more accurate and faster response than the simple discretization of conventional continuous time based methods using approximate discretization rules.

The present disclosure provides a discrete PLL system, referred to as dPLL-UH, which provides detection of an angular frequency, and additionally both the positive and negative sequences of a fundamental wave component of an unbalanced and distorted three-phase signal.

Characteristics of the dPLL-UH scheme can be listed as follows:
(i) The dPLL-UH method includes a harmonic compensation mechanism to deal with the harmonic distortion present in a reference signal. It does not require transformation of variables into synchronous reference frame coordinates, as is the case in most PLL schemes. Moreover, the synchronization process is based on detection of a fundamental frequency.
(ii) The design of the dPLL-UH is based on a more complete and generic discrete model description of an unbalanced three-phase reference periodic signal, which can be distorted by unbalanced low order harmonics.
(iii) The dPLL-UH method provides accurate responses in cases of a low sampling frequency. This is in contrast to discretization of continuous based PLL using simple approximate discretization rules, which may lead to considerable errors.

Therefore, the dPLL-UH performs properly in cases of a relatively low sampling frequency, for reference signals showing unbalanced conditions, sags, swells, and angular frequency variations, for example. Moreover, as the method is provided with an explicit discrete harmonic compensation mechanism (dCM-UH), it is able to reduce the effects of low-harmonics distortion without compromising the speed of response, thus providing a fast and precise response.

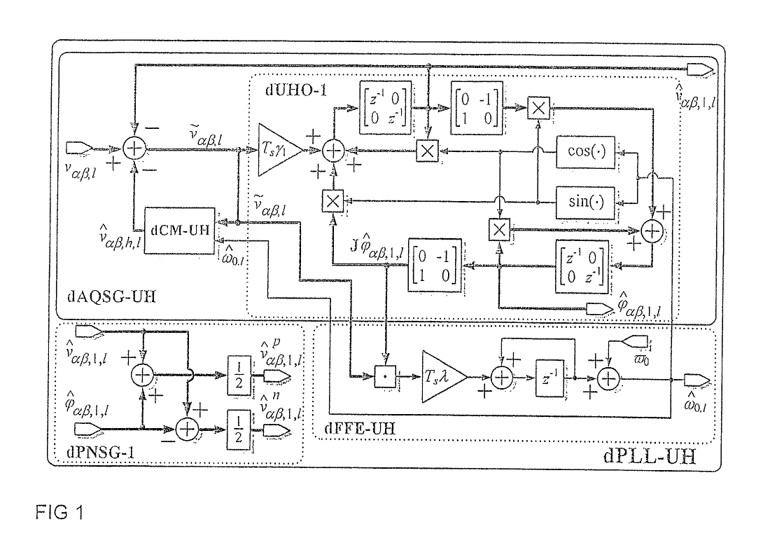

The method of the present disclosure is able to deliver detected values for positive and negative sequences of a measured reference signal ν_{αβ}, as well as a detected value of the fundamental frequency ω₀. The present scheme is a discrete PLL method referred to as dPLL-UH as it appropriately handles the operation under unbalanced and harmonic distortion. The method is of special interest in cases of a low sampling frequency, where the discretization of continuous time PLL schemes, by means of approximate discretization rules, may fail to achieve the correct detected values. The dPLL-UH includes a discrete detector for the fundamental wave component of the measured reference signal (dAQSG-UH), a generator of the positive and negative sequences (dPNSG), and a discrete detector for the fundamental frequency (dFFE-UH). To cope with the harmonic distortion present in the reference signal, an exemplary embodiment also includes a discrete harmonic compensation mechanism (dCM-UH). A schematic of the proposed dPLL-UH including all elements is depicted in FIG. 1. In this diagram, thick lines represent vector variables, while normal lines represent scalar variables. The design of discrete estimators dAQSG-UH, dFFE-UH, and dCM-UH is based on a quite general discrete model for a three-phase signal, which will be described next for ease of reference.

### Discrete Model of a Three-Phase Unbalanced Distorted Signal

First, a model to describe a three-phase unbalanced periodic signal ν_{αβ} is formed. This model assumes that the signal ν_{αβ} is composed of a fundamental and higher order harmonics components of the fundamental frequency ω₀, having harmonic indexes in the set H={1,3,5, . . . }. The model is given by

$${\dot{v}}_{αβ , k} = k {ω}_{0} J {ϕ}_{αβ , k} , ∀ k ∈ H \\ {\dot{ϕ}}_{αβ , k} = k {ω}_{0} {Jv}_{αβ , k} \\ {v}_{αβ} = {\sum }_{k ∈ H} {v}_{αβ , k} \qquad ( 1 )$$

where J is a skew symmetric matrix defined by

$$J = [ \begin{matrix}0 & - 1 \\ 1 & 0\end{matrix} ] , {J}_{T} = - J \qquad ( 2 )$$

variable ν_{αβ,k} is the k-th harmonic component, and φ_{αβ,k} is an auxiliary variable necessary for completing the model description and meaningful only in an unbalanced case. In fact, these variables can be described using symmetric components to address the unbalanced case as follows

ν_{αβ,k}=ν_{αβ,k}^{p}+ν_{αβ,k}ⁿ, ∀k∈H

φ_{αβ,k}=ν_{αβ,k}^{p}+ν_{αβ,k}ⁿ (3)

where ν_{αβ,k}^{p} and ν_{αβ,k}ⁿ represent the positive and negative sequence components of ν_{αβ,k}, respectively. Thus, the auxiliary variable is the difference between the positive symmetric component and the negative symmetric component of the periodic signal in question. In particular, for the fundamental wave component we have

$$[ \begin{matrix}{v}_{αβ , 1} \\ {ϕ}_{αβ , 1}\end{matrix} ] = [ \begin{matrix}{I}_{2} & {I}_{2} \\ {I}_{2} & - {I}_{2}\end{matrix} ] [ \begin{matrix}{v}_{αβ , 1}^{p} \\ {v}_{αβ , 1}^{n}\end{matrix} ] \qquad ( 4 )$$

where 1₂ is the 2×2 identity matrix. Notice that the positive and negative sequences can be recuperated out of (4).

Exact discretization of the k-th harmonic component model (1) using the state space transformation method based on the exponential matrix yields

$$[ \begin{matrix}{v}_{αβ , k , l + 1} \\ {ϕ}_{αβ , k , l + 1}\end{matrix} ] = {e}^{A ( k {ω}_{0} {T}_{s} )} [ \begin{matrix}{v}_{αβ , k , l} \\ {ϕ}_{αβ , k , l}\end{matrix} ] , ∀ k ∈ H \qquad ( 5 )$$

where Tₛ represents the sampling time, xₗ is the l-th sample of variable x, and matrix e^{A(kω}^{₀}^{T}^{ₛ}⁾ is given by

$${e}^{A ( k {ω}_{0} {T}_{s} )} = [ \begin{matrix}cos ( k {ω}_{0} {T}_{s} ) & 0 & 0 & - sin ( k {ω}_{0} {T}_{s} ) \\ 0 & cos ( k {ω}_{0} {T}_{s} ) & sin ( k {ω}_{0} {T}_{s} ) & 0 \\ 0 & - sin ( k {ω}_{0} {T}_{s} ) & cos ( k {ω}_{0} {T}_{s} ) & 0 \\ sin ( k {ω}_{0} {T}_{s} ) & 0 & 0 & cos ( k {ω}_{0} {T}_{s} )\end{matrix} ] . \qquad ( 6 )$$

At this point, it is important to distinguish between l and k. Notice that l is used to address the l-th sample in the discrete representation, while k is used to address the k-th harmonic component.

Model (5) can also be written, using the skew-symmetric matrix J, as follows

ν_{αβ,k,l+1}=cos(kω₀Tₛ)ν_{αβ,k,l}+J sin(kω₀Tₛ)φ_{αβ,k,l}

φ_{αβ,k,l+1}=J sin(kω₀Tₛ)ν_{αβ,k,l}+cos(kω₀Tₛ)φ_{αβ,k,l}, (7)

wherefrom the l-th sample of signal ν_{αβ} can be reconstructed as

$${v}_{αβ , l} = {\sum }_{k ∈ H} {v}_{αβ , k , l} . \qquad ( 8 )$$

Similar to (3), we can describe the discrete variables ν_{αβ,k,l} and φ_{αβ,k,l} in terms of their symmetric components as follows

ν_{αβ,k,l}=ν_{αβ,k,l}^{p}+ν_{αβ,k,l}ⁿ, ∀k∈H

φ_{αβ,k,l}=ν_{αβ,k,l}^{p}−ν_{αβ,k,l}ⁿ. (9)

Notice that positive and negative sequences can be recuperated out of (9).

It is to be noted that in a balanced case ν_{αβ,k,l}ⁿ=0, ν_{αβ,k,l}=φ_{αβ,k,l}, ∀k∈H. Therefore, in the balanced case the discrete model (7) can be reduced to

ν_{αβ,k,l+1}=cos(kω₀Tₛ)ν_{αβ,k,l}+J sin(kω₀Tₛ)ν_{αβ,k,l}. (10)

Discrete Detector of the Fundamental Wave Component—dAQSG-UH

Based on model (7) to (8), the following discrete detector is constructed for the k-th (k ∈ H) harmonic component of the reference signal ν_{αβ,l} which includes a copy of the system model (7) to which a damping term is added, that is,

$${\hat{v}}_{αβ , k , l + 1} = cos ( k {\hat{ω}}_{0 , l} {T}_{s} ) {\hat{v}}_{αβ , k , l} + J sin ( k {\hat{ω}}_{0 , l} {T}_{s} ) {\hat{ϕ}}_{αβ , k , l} + {T}_{s} {γ}_{k} {\tilde{v}}_{αβ , l} , \\ ∀ k ∈ H \\ {\hat{ϕ}}_{αβ , k , l + 1} = J sin ( k {\hat{ω}}_{0 , l} {T}_{s} ) {\hat{v}}_{αβ , k , l} + cos ( k {\hat{ω}}_{0 , l} {T}_{s} ) {\hat{ϕ}}_{αβ , k , l} \\ {\hat{v}}_{αβ , l} = {\sum }_{k ∈ H} {\hat{v}}_{αβ , k , l} \qquad ( 11 )$$

where γₖ (k ∈ H) are positive design parameters used to introduce the required damping; \hat{ω}_{0,l} is the detected value of the l-th sample of the fundamental frequency ω_{0,l}; \hat{ν}_{αβ,k,l} and \hat{φ}_{αβ,k,l} are the detected values of ν_{αβ,k,l} and φ_{αβ,k,l}, respectively; we have now defined the error \tilde{ν}_{αβ,l}=ν_{αβ,l}−\hat{ν}_{αβ,l}, with \hat{ν}_{αβ,l} representing the overall detected signal. In fact, the detected signal \hat{ν}_{αβ,l} can be decomposed as follows

\hat{ν}_{αβ,l}=\hat{ν}_{αβ,1,l}+\hat{ν}_{αβ,h,l} (12)

where \hat{ν}_{αβ,1,l} represents the detected value of the fundamental wave component ν_{αβ,1,l} and \hat{ν}_{αβ,h,l} represents a detected value of the harmonic distortion of the measured signal, i.e. the sum of all higher order harmonics.

In accordance with an exemplary embodiment, the fundamental wave component \hat{ν}_{αβ,1,l} can be reconstructed, based on (11), according to

\hat{ν}_{αβ,1,l+1}=cos(\hat{ω}₀Tₛ)\hat{ν}_{αβ,1,l}+J sin(\hat{ω}₀T)\hat{φ}_{αβ,1,l}+Tγ₁\tilde{ν}_{αβ,l}

\hat{φ}_{αβ,1,l+1}=J sin(\hat{ω}₀T)\hat{ν}_{αβ,1,l}+cos(\hat{ω}₀T)\hat{φ}_{αβ,1,l}. (13)

The fundamental wave components \hat{ν}_{αβ,1,l} and \hat{φ}_{αβ,1,l}, obtained from this discrete detector are vectors, each formed by two signals in quadrature. Therefore, detector (13) is referred to as the discrete detector of the fundamental wave component for unbalanced operation conditions and harmonic distortion (dAQSG-UH). FIG. 1 shows that the dAQSG-UH is composed by a basic block referred to as the discrete unbalanced harmonic oscillator tuned at the fundamental frequency (dUHO-1), plus a feedback path.

In the balanced case, the detector for the fundamental wave component can be reduced to

\hat{ν}_{αβ,1,l+1}=cos(\hat{ω}₀Tₛ)\hat{ν}_{αβ,1,l}+J sin(\hat{ω}₀Tₛ)\hat{ν}_{αβ,1,l}+Tₛγ₁\tilde{ν}_{αβ,l}

\tilde{ν}_{αβ,l}=ν_{αβ,l}−\hat{ν}_{αβ,l}

\hat{ν}_{αβ,l}=\hat{ν}_{αβ,1,l}+\hat{ν}_{αβ,h,l} (14)

where \hat{ν}_{αβ,h,l} has to be redefined for the balanced case as will be shown in (17).
Positive and Negative Sequences Generator—dPNSG-1

Based on relationship (9), the positive and negative sequences of the fundamental wave component of the reference signal can be reconstructed according to

$${\hat{v}}_{αβ , 1 , l}^{p} = \frac{1}{2} ( {\hat{v}}_{αβ , 1 , l} + {\hat{ϕ}}_{αβ , 1 , l} ) \\ {\hat{v}}_{αβ , 1 , l}^{n} = \frac{1}{2} ( {\hat{v}}_{αβ , 1 , l} + {\hat{ϕ}}_{αβ , 1 , l} ) \qquad ( 15 )$$

where detected values \hat{ν}_{αβ,1,l} and \hat{φ}_{αβ,1,l} are obtained as shown in the dAQSG-UH (13).

Scheme (15) is referred to as a generator of positive and negative sequences of the fundamental wave component (dPNSG-1). In accordance with an exemplary embodiment, the positive sequence component \hat{ν}_{αβ,1,l}^{p} is a pure sinusoidal balanced signal, which is in phase with the reference signal ν_{αβ,l}. This signal can now be used as a synchronization signal, to design a cleaner current reference, or as a transformation basis to represent variables in the synchronous frame.

Discrete Harmonic Compensation Mechanism—dCM-UH

This mechanism, referred to as dCM-UH, has the purpose of detecting a harmonic distortion part of the reference signal, i.e. ν_{αβ,h,l}. For harmonic rejection purposes, this signal is later subtracted from the original signal as shown in the scheme of FIG. 1. Moreover, the dCM-UH block can be seen as an optional plug-in block, in the sense that it can be eliminated in the case of negligible harmonic distortion, leading to a considerably simpler scheme.

The design of this detector is based on (11) as shown below

$${\hat{v}}_{αβ , k , l + 1} = cos ( k {\hat{ω}}_{0} {T}_{s} ) {\hat{v}}_{αβ , k , l} + J sin ( k {\hat{ω}}_{0} {T}_{s} ) {\hat{φ}}_{αβ , k , l} + {T}_{s} {γ}_{k} {\tilde{v}}_{αβ , l} , \\ ∀ k ∈ \{ 3 , 5 , … \} \\ {\hat{ϕ}}_{αβ , k , l + 1} = J sin ( k {\hat{ω}}_{0} {T}_{s} ) {\hat{v}}_{αβ , k , l} + cos ( k {\hat{ω}}_{0} {T}_{s} ) {\hat{φ}}_{αβ , k , l} \\ {\hat{v}}_{αβ , h , l} = {\sum }_{k ∈ \{ 3 , 5 , … \}} {\hat{v}}_{αβ , k , l} \qquad ( 16 )$$

where γₖ (k ∈ {3,5, . . . }) are positive design parameters, and J=−J^{T} is the skew symmetric matrix defined above. That is, each harmonic component \hat{ν}_{αβ,k,l} (k ∈ {3,5, . . . }) is detected according to (16), which are then accumulated in a single signal \hat{ν}_{αβ,h,l}.

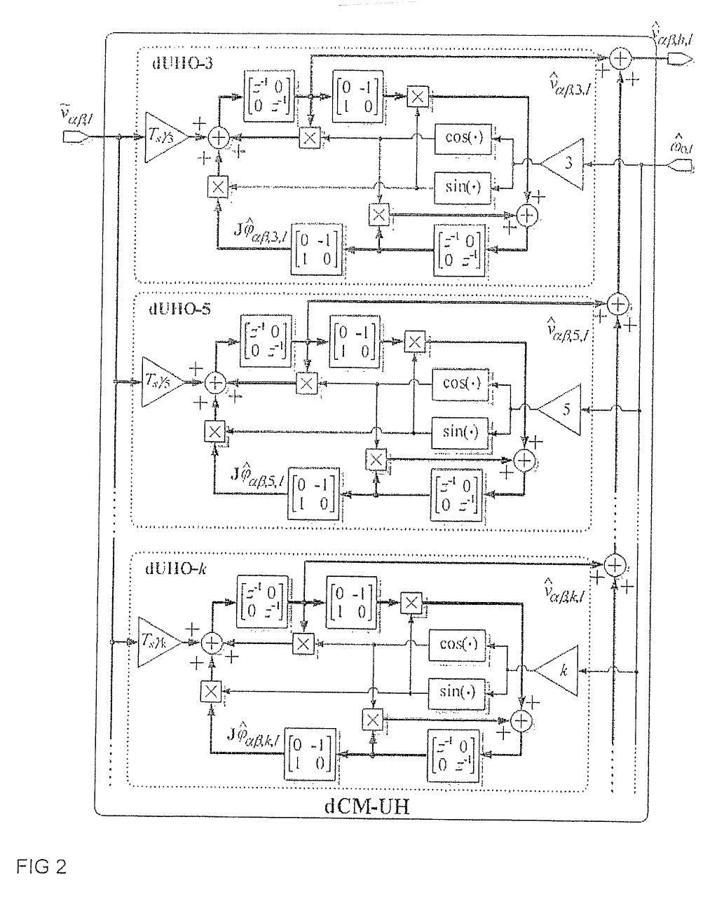

A block diagram of the dCM-UH given by (16) is presented in FIG. 2. Notice that the dCM-UH is composed of a bank of basic blocks referred to as discrete unbalanced harmonic oscillators, each of them being tuned at the k-th harmonic under concern (dUHO-k).

For the balanced case, the harmonics compensation mechanism, for example, the detection of the harmonic part of the reference signal, is reduced to

$${\hat{v}}_{αβ , k , l + 1} = cos ( k {\hat{ω}}_{0} {T}_{s} ) {\hat{v}}_{αβ , k , l} + J sin ( k {\hat{ω}}_{0} {T}_{s} ) {\hat{v}}_{αβ , k , l} + {T}_{s} {γ}_{k} {\tilde{v}}_{αβ , l} , \\ ∀ k ∈ \{ 3 , 5 , … \} \\ {\hat{v}}_{αβ , h , l} = {\sum }_{k ∈ \{ 3 , 5 , … \}} {\hat{v}}_{αβ , k , l} . \qquad ( 18 )$$

The dCM-UH can be used or not, depending on the level of harmonic distortion present in the reference signal. If the dCM-UH is not used, the basic scheme, referred to as dPLL-U, still has certain robustness against harmonic distortion present in the measured reference signal owing to its selective nature. In this case, harmonic distortion rejection can be improved at the cost of limiting the bandwidth of the overall scheme, which reduces the speed of response and thus deteriorates the dynamical performance of the overall PLL scheme.

Discrete Fundamental Frequency Detector—dFFE-UH

Reconstruction of variable \hat{ω}_{0,l} involved in the dAQSG-UH (13) and in the dCM-UH (16) is performed by the following discrete fundamental frequency detector

$${\tilde{ω}}_{0 , l + 1} = {\tilde{ω}}_{0 , l} + {T}_{s} λ {\tilde{v}}_{αβ , l}^{T} J {\hat{ϕ}}_{αβ , 1 , l} \\ {\hat{ω}}_{0 , l} = {\tilde{ω}}_{0 , l} + {ϖ}_{0} \qquad ( 18 )$$

where λ>0 is a design parameter representing the adaptation gain, and ω̅₀ represents a nominal value of the fundamental frequency and is included in the dFFE-UH as a feedforward term to prevent high transients during the startup operation. This estimator is referred to as a discrete fundamental frequency detector for unbalanced operation and distorted conditions (dFFE-UH).

The discrete fundamental frequency detector in the balanced case is reduced to

\tilde{ω}_{0,l+1}=\tilde{ω}_{0,l}+Tₛλ\tilde{ν}_{αβ,l}^{T}J\hat{ν}_{αβ,1,l}

\hat{ω}_{0,l}=\tilde{ω}_{0,l}+ ω̅₀. (19)

Tuning of the dPLL-UH Method

For the tuning of λ and γ₁ it is recommended to follow the following tuning rules

$${γ}_{1} = \frac{9}{{τ}_{s}} \\ λ = {( \frac{4.5}{{τ}_{s} \vert {v}_{αβ} \vert} )}^{2} \qquad ( 20 )$$

where τₛ represents the desired settling time, which is somehow related to the desired bandwidth of the overall scheme. These tuning rules may give a first approximation, and a refinement process must be followed.

For gains γₖ (k ∈ {3,5, . . . })the following rules are proposed

$${γ}_{k} = \frac{2.2}{{τ}_{s , k}} , ( k ∈ \{ 3 , 5 , … \} ) \qquad ( 21 )$$

where τ_{s,k} represents the desired settling time for the envelope of the k-th harmonic component. In this case, it is assumed that the dUHO-k only influences the corresponding k-th harmonic, and that the dynamics of the simplified system (not including the dCM-UH) is, as mentioned above, a stable second order system. The influence of the simplified system is thus neglected, and each dUHOs can be tuned separately. As above, we have affected each γₖ (k ∈ {3,5, . . . }) by the sampling time Tₛ.

### Compensation of the Implementation Delay

As the delivered signal \hat{ν}_{αβ,1,l}^{p} out of the dPLL-UH is a balanced sinusoidal signal, it may be represented as

$${\hat{v}}_{αβ , 1 , l}^{p} = {e}^{J {\hat{ω}}_{0} {lT}_{s}} {\hat{V}}_{dq , l} \\ where \\ {e}^{J {\hat{ω}}_{0} {lT}_{s}} = [ \begin{matrix}cos ( {\hat{ω}}_{0} {lT}_{s} ) & - sin ( {\hat{ω}}_{0} {lT}_{s} ) \\ sin ( {\hat{ω}}_{0} {lT}_{s} ) & cos ( {\hat{ω}}_{0} {lT}_{s} )\end{matrix} ] \qquad ( 22 )$$

is a rotation matrix, and

$${\hat{V}}_{dq , l} = [ \begin{matrix}{\hat{V}}_{d , l} \\ {\hat{V}}_{q , l}\end{matrix} ]$$

is the phasor of \hat{ν}_{αβ,1,l}^{p} at the l-th sampling instant, with \hat{V}_{d,l} as as real and \hat{V}_{q,l} as imaginary components, which are assumed to be constants.

Due to the digital implementation, the delivered signal \hat{ν}_{αβ,1,l}^{p} will exhibit an inherent delay of one sample time Tₛ. Therefore, a more realistic representation for such a signal would be

$${{v}^{\overline{\hat{}}}}_{αβ , 1 , l}^{p} = {e}^{J {\hat{ω}}_{0} ( l - 1 ) {T}_{s}} {\hat{V}}_{dq , l} \qquad ( 23 )$$

where the bar notation is used to refer to the delayed signal.

Notice that, using the properties of the rotation e^{J\hat{ω}}^{₀}^{(l-1)T}^{ₛ} this can also be expressed as

$$\begin{matrix}{{v}^{\overline{\hat{}}}}_{αβ , 1 , l}^{p} = {e}^{- J {\hat{ω}}_{0} {T}_{s}} {e}^{J {\hat{ω}}_{0} {lT}_{s}} {\hat{V}}_{dq , l} \\ = {e}^{- J {\hat{ω}}_{0} {T}_{s}} {\hat{v}}_{αβ , 1 , l}^{p} .\end{matrix} \qquad ( 24 )$$

Thus, to compensate for the delay, and thus to recuperate the non-delayed signal \hat{ν}_{αβ,1,l}^{p}, it is enough to rotate the delayed signal {circumflex over ( ν̅_{αβ,1,l}^{p} counter-wise as follows

$${\hat{v}}_{αβ , 1 , l}^{p} = {e}^{J {\hat{ω}}_{0} {T}_{s}} {{v}^{\overline{\hat{}}}}_{αβ , 1 , l}^{p} \qquad ( 25 )$$

where the rotation matrix e^{K\hat{ω}}^{₀}^{T}^{ₛ} is given by

$${e}^{J {\hat{ω}}_{0} {T}_{s}} = [ \begin{matrix}cos ( {\hat{ω}}_{0} {T}_{s} ) & - sin ( {\hat{ω}}_{0} {T}_{s} ) \\ sin ( {\hat{ω}}_{0} {T}_{s} ) & cos ( {\hat{ω}}_{0} {T}_{s} )\end{matrix} ] . \qquad ( 26 )$$

Notice that for an arbitrarily small Tₛ this matrix converges towards the 2×2 identity matrix I₂, thus yielding no compensation effect.

### Numerical Results

For the numerical results, the following parameters have been selected λ=1.1 and γ₁=400 , which approximately correspond to a settling time of τₛ=0.025 s. It is assumed that the reference signal also contains 3rd and 5th harmonics, and thus the dCM-UH contains dUHO-3 and dUHO-5 tuned at these harmonics.

The gains in the dCM-UH are fixed to γ₃=γ₅=100, which correspond to the settling time of τ_{s,3}=τ_{s,5}=22 ms for both UHOs. The reference signal has a nominal frequency of ω̅=314.16 rad/s (50 Hz), and an approximate amplitude of |ν_{αβ}|=100 V. Unless otherwise stated, a sampling time of 250 μs is considered, which corresponds to a sampling frequency of 4 kHz. The following test cases have been considered for the reference signal ν_{αβ}.
(i) Balanced condition. The reference signal is formed only by a positive sequence of 100 V of amplitude, and fundamental frequency of 314.16 rad/s (50 Hz), with a zero phase shift.
(ii) Unbalanced condition. The reference signal includes both a positive and a negative sequence component. The positive sequence has 100 V of amplitude at 314.16 rad/s (50 Hz) and a zero phase shift. For the negative sequence, an amplitude of 30 V and a zero phase shift are considered.
(iii) Harmonic distortion. Harmonics 3rd and 5th are added to the previous unbalanced signal to create a periodic distortion. Both harmonics also have a negative sequence component to allow unbalance in harmonics as well.
(iv) Frequency variations. A step change is introduced in the fundamental frequency of the reference signal, changing from 314.16 rad/s (50 Hz) to 219.9 rad/s (35 Hz).

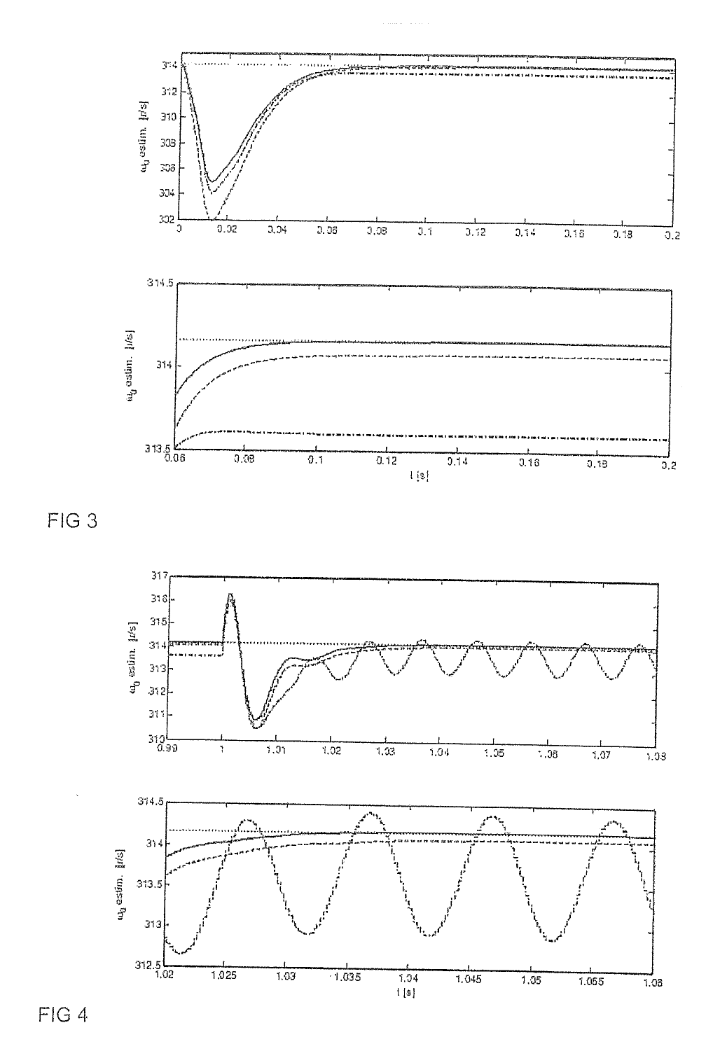

FIG. 3 shows transient responses during start up of a detected fundamental frequency using the proposed dPLL-UH and a discretized UH-PLL, according to an exemplary embodiment of the present disclosure. The UH-PLL has been discretized by using a Euler's backward (rectangular) approximation. Moreover, the implementation of the discrete UH-PLL has been modified in such a way to use, whenever possible, the latest updated intermediate available terms to evaluate the discretized expressions. This yields better results than using the one step delayed values exclusively to evaluate expressions, as formally marked by theory, where bigger errors appear and also oscillations may be observed due to unbalance as observed in FIG. 3. However, even with this improved discretization of UH-PLL, it is shown that it cannot reach the reference value of the fundamental frequency. Notice in FIG. 3 that this method (in dashed line) stabilizes in 314.08 rad/s, while the regular discretization (in dash-dotted line) stabilizes at 313.595. In contrast, the proposed dPLL-UH (in solid line) reaches the correct value of the reference frequency ω₀=314.16 rad/s after a relatively short transient. The sampling frequency is fixed to 4 kHz. The lower plot of FIG. 3 shows a zoom of the upper plot.

FIG. 4 shows a transient response of a detected frequency during a change from a balanced to an unbalanced condition. Notice that the steady state error in the response of the improved discretization of UH-PLL remains the same after a short transient. However, the response of the regular discretization now exhibits some oscillations. FIG. 4 shows in solid line the proposed dPLL-UH, in dash-dot line regular discretization of UH-PLL using Euler's backward rule, and in dashed line improved discretization of UH-PLL. A zoom of the upper plot is shown in the lower plot. The sampling frequency is fixed to 4 kHz.

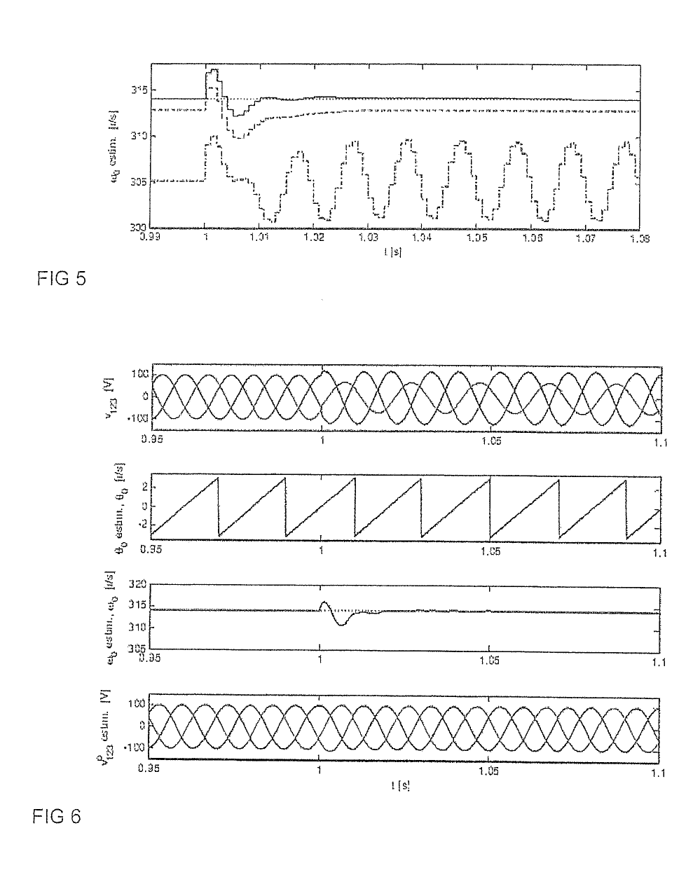

As expected, the steady state error becomes even bigger for a lower sampling frequency. For instance, FIG. 5 shows that for a sampling frequency of 1 kHz the improved discretization of UH-PLL now stabilizes at 312.87 rad/s, while the regular discretization of UH-PLL stabilizes at 305.117 rad/s before unbalanced operation. The performance of the present disclosure is shown in solid line, regular discretization of UH-PLL using Euler's backward rule is shown in dash-dot line, and improved discretization of UH-PLL in dashed line.

In the above tests we have not considered harmonic distortion to clearly see steady state errors.

FIG. 6 shows a transient response obtained with the proposed dPLL-UH when the reference signal changes from a balanced to an unbalanced operation condition at time t=1 s, in accordance with an exemplary embodiment of the present disclosure. FIG. 6 shows (from top to bottom) the reference signal in three-phase coordinates ν₁₂₃, detected phase angle \hat{θ}₀, detected angular frequency \hat{ω}₀, and detected positive-sequence of the fundamental wave component in three-phase coordinates \hat{ν}_{123,1}^{p}. The sampling frequency is fixed to 4 kHz. Notice that, after a relatively short transient, all signals return to their desired values. For instance, it is observed that the detected phase angle \hat{θ}₀ (solid line) follows perfectly well the true phase angle (dashed line) after an almost imperceptible transient. The detected frequency \hat{ω}₀ (solid line) is also maintained in its reference fixed to 316.14 rad/s (dotted line) after a small transient. Moreover, the detected positive-sequence of the fundamental wave component \hat{ν}_{123,1}^{p} has an almost imperceptible variation.

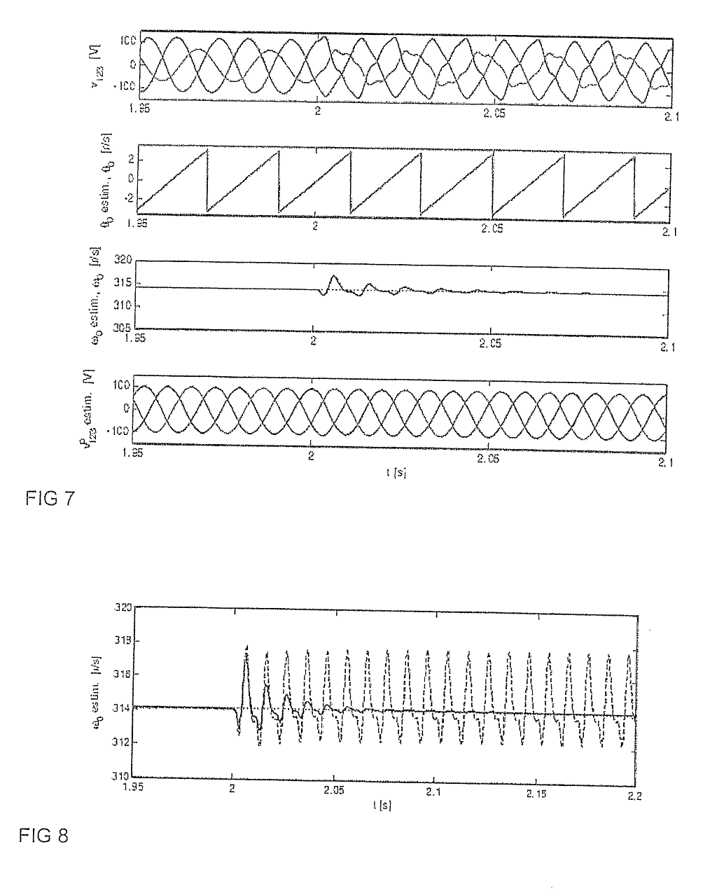

FIG. 7 shows a transient response of the proposed dPLL-UH when harmonic distortion is added to the already unbalanced reference signal at t=2 s. FIG. 7 shows (from top to bottom) the reference signal in three-phase coordinates ν₁₂₃ , detected phase angle \hat{θ}₀, detected angular frequency \hat{ω}₀, and detected positive-sequence of the fundamental wave component in three-phase coordinates \hat{ν}_{123,1}^{p}. The sampling frequency is fixed to 4 kHz. Notice that, after a relatively short transient, all signals return to their desired values. In particular, notice that the detected frequency \hat{ω}₀ (solid line) is also maintained in its reference fixed to 316.14 rad/s (dotted line) after a small transient, without further fluctuations. Moreover, notice that the detected positive-sequence of the fundamental wave component \hat{ν}_{123,1}^{p}, as well as the detected phase angle \hat{θ}₀, have an almost imperceptible transient.

FIG. 8 shows a transient response of the proposed dPLL-UH and dPLL-U when the harmonic distortion is added to an already unbalanced reference signal at t=2 s. Recall that the dPLL-U is a simplified version of the dPLL-UH, which does not include the harmonic compensation mechanism dCM-UH. Notice that, before t=2 s, both methods reach the desired reference, as both are equipped to properly handle unbalance. However, in contrast to the response of the d-PLL-UH, the dPLL-U response has persistent fluctuations after the harmonic distortion is included, that is the dPLL-U is not able to reject this type of disturbances.

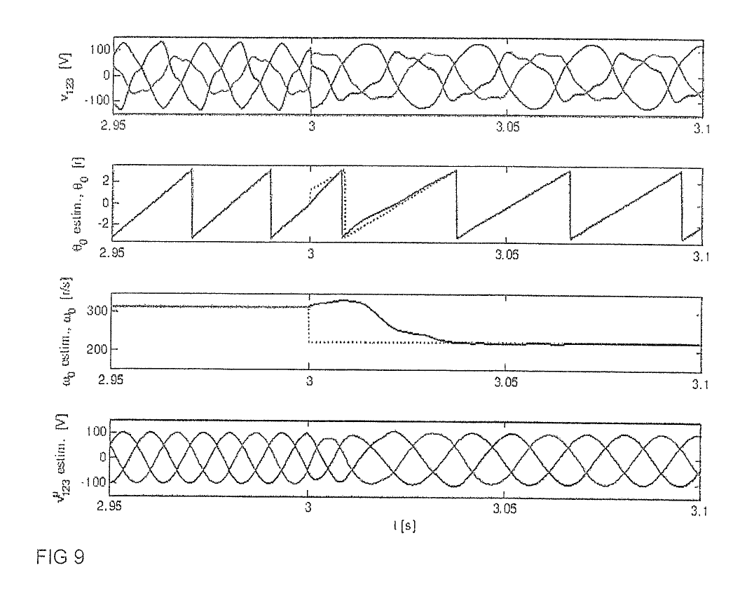

FIG. 9 shows a transient response of the proposed dPLL-UH to a step change in the angular frequency of the reference signal changing from 314.16 rad/s (50 Hz) to 219.9 rad/s (35 Hz) at t=3 s. FIG. 9 shows (from top to bottom) the reference signal in three-phase coordinates ν₁₂₃, detected phase angle \hat{θ}₀, detected angular frequency \hat{ω}₀, and detected positive-sequence of the fundamental wave component in three-phase coordinates \hat{ν}_{123,1}^{p}. It is shown that after a short transient, the detected phase angle follows perfectly well the true phase angle. It is shown that the detected fundamental frequency, starting at a reference of 314.16 rad/s (50 Hz) , reaches its new reference fixed to 219.9 rad/s (35 Hz) in a relatively short time. The bottom plot shows that the detected positive sequence signals maintain their amplitude after a relatively short transient.

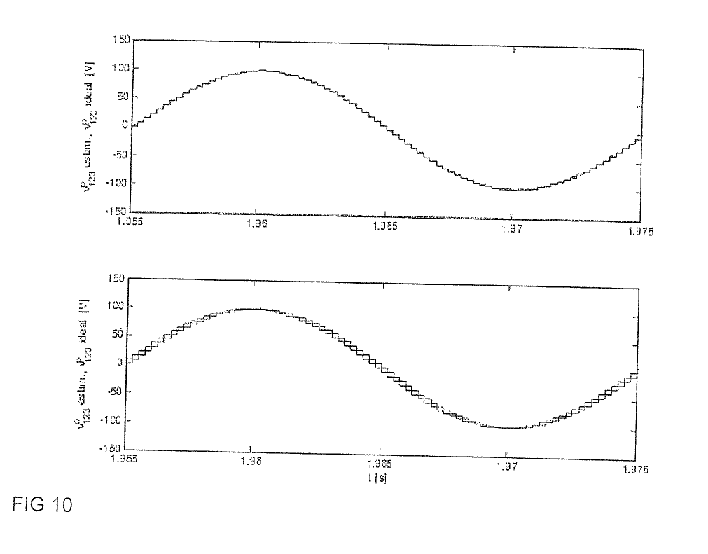

FIG. 10 shows a benefit of the compensation mechanism for the implementation delay proposed in (22) to (23). It is observed in the top plot that, with this compensation, both the theoretical sampled positive sequence of the fundamental wave component and its detected value are practically one over the other. However, it is observed in the bottom plot that, without this compensation, a phase shift equivalent to one sampling period arises in between both signals.

FIG. 10 only shows coordinate 1 \hat{ν}_{1,1}^{p} of the three-phase coordinates and the corresponding sampled theoretical positive-sequence of the fundamental wave component ν_{1,1}^{p}.

In the above, the disclosure and its embodiments are described generally relating to a reference voltage the frequency of which is to be detected. It is clear that this reference voltage can be, for example, a measured mains voltage with which a device having the implementation of the disclosure is to be synchronized.

It will be appreciated by those skilled in the art that the present invention can be embodied in other specific forms without departing from the spirit or essential characteristics thereof. The presently disclosed embodiments are therefore considered in all respects to be illustrative and not restricted. The scope of the invention is indicated by the appended claims rather than the foregoing description and all changes that come within the meaning and range and equivalence thereof are intended to be embraced therein.

What is claimed is:

1. A method of detecting a frequency of a measured three-phase voltage, the method comprising:
measuring the three-phase voltage (ν_{αβ});
forming a discrete model for a periodic signal, the discrete model including the three-phase voltage (ν_{αβ}) and a difference (φ_{αβ,k}) between a positive voltage component and a negative voltage component of the three-phase voltage as model variables;
forming a discrete detector based on the formed discrete model; and
detecting a fundamental wave component of the voltage (\hat{ν}_{αβ,1}) and the difference (\hat{φ}_{αβ,1}) between the positive voltage component and the negative voltage component of the three-phase voltage from an error (\tilde{ν}_{αβ}) between the measured voltage (ν_{αβ}) and the detected fundamental wave component of the voltage (\hat{ν}_{αβ,1}) by using the discrete detector and a sampling time (Tₛ) together with a detected frequency (\hat{ω}₀) of the measured voltage,
wherein the detected frequency (\hat{ω}₀) of the measured voltage is detected from a detected difference (\hat{φ}_{αβ,k}) between positive and negative voltage components of the measured voltage and from the error (\tilde{ν}_{αβ}) between the measured voltage (ν_{αβ}) and the detected fundamental wave component of the voltage (\hat{ν}_{αβ,1}) in an adaptation mechanism.

2. A method according to claim 1, comprising:
calculating a positive sequence component of the fundamental wave component of the voltage from the detected fundamental wave component and the difference,
wherein the positive sequence component of the fundamental frequency component has the frequency of the measured three-phase voltage.

3. A method according to claim 2, comprising:
rotating the detected positive sequence component of the fundamental frequency component on the basis of the sampling time and detected frequency for taking into account a delay in the discrete detector.

4. A method according to claim 1, comprising:
detecting one or more of harmonic components of a measured voltage signal by using the detected frequency of the measured voltage and the error (\tilde{ν}_{αβ}) between the measured voltage (ν_{αβ}) and the detected fundamental wave component of the voltage (\hat{ν}_{αβ,1}).

5. A method according to claim 4, wherein the detected harmonic components are further removed from the detected fundamental voltage component.

6. An arrangement for detecting the frequency of a measured three-phase voltage, comprising:
means for measuring the three-phase voltage (ν_{αβ});
a discrete model for a periodic signal, the discrete model including the three-phase voltage (ν_{αβ}) and a difference (φ_{αβ,k}) between a positive voltage component and a negative voltage component of the three-phase voltage as model variables;
a discrete detector based on the formed discrete model; and
means for detecting a fundamental wave component of the voltage (\hat{ν}_{αβ,1}) and the difference (\hat{φ}_{αβ,1}) between the positive voltage component and the negative voltage component of the three-phase voltage from an error (\tilde{ν}_{αβ}) between the measured voltage (ν_{αβ}) and the detected fundamental wave component of the voltage(ν_{αβ,1}) by using the discrete detector and a sampling time (Tₛ) together with a detected frequency (\hat{ω}₀) of the measured voltage,
wherein the detected frequency (\hat{ω}₀) of the measured voltage is detected from a detected difference (\hat{φ}_{αβ,k}) between positive and negative voltage components of the measured voltage and from the error (\tilde{ν}_{αβ}) between the measured voltage (ν_{αβ}) and the detected fundamental wave component of the voltage (\hat{ν}_{αβ,1}) in an adaptation mechanism.

7. A method according to claim 2, comprising:
detecting one or more of harmonic components of a measured voltage signal by using the detected frequency of the measured voltage and the error (\tilde{ν}_{αβ}) between the measured voltage (ν_{αβ}) and the detected fundamental wave component of the voltage (\hat{ν}_{αβ,1}).

8. A method according to claim 7, wherein the detected harmonic components are further removed from the detected fundamental voltage component.

9. A method according to claim 3, comprising:
detecting one or more of harmonic components of a measured voltage signal by using the detected frequency of the measured voltage and the error (\tilde{ν}_{αβ}) between the measured voltage (ν_{αβ}) and the detected fundamental wave component of the voltage (\hat{ν}_{αβ,1}).

10. A method according to claim 9, wherein the detected harmonic components are further removed from the detected fundamental voltage component.
